(19) United States
(12) Patent Application Publication
(10) Pub. No.: US 2015/0333029 A1
(43) Pub. Date: Nov. 19, 2015

(54) PACKAGE SUBSTRATE AND METHOD FOR FABRICATING THE SAME

(71) Applicant: Siliconware Precision Industries Co., Ltd., Taichung (TW)

(72) Inventors: Yu-cheng Pai, Taichung (TW); Chun- Hsien Lin, Taichung (TW); Shih-Chao Chiu, Taichung (TW); Wei-Chung Hsiao, Taichung (TW); Ming-Chen Sun, Taichung (TW); Tzu-Chieh Shen, Taichung (TW); Chia-Cheng Chen, Taichung (TW)

(21) Appl. No.: 14/459,713

(22) Filed: Aug. 14, 2014

(30) Foreign Application Priority Data
May 13, 2014 (TW) 103116793

(51) Int. Cl. H01L 23/00; H01L 23/48

(52) U.S. Cl. CPC H01L 24/17; H01L 23/481; H01L 24/09; H01L 24/03; H01L 24/11; H01L 2224/02185; H01L 2224/0219

(57) ABSTRACT

A package substrate and a method of fabricating the same are provided. The method includes providing a substrate body having a first surface, a second surface opposing the first surface, a plurality of first electrical connecting pads disposed on the first surface; mounting a metal board on the first electrical connecting pads; and patterning the metal board so as to define a plurality of metal pillars corresponding to the first electrical connecting pads. Therefore, drawbacks of raw edges and unequal heights of the metal pillars can be obviated.

### BACKGROUND OF THE INVENTION

1. Field of the Invention

The present invention relates to package substrates and a method for fabricating the same, and, more particularly, to a package on package (PoP) and a method for fabricating the same

2. Description of Related Art

Recently, with the increasingly smaller, lightweight and thinner profile in all types of electronic products, package on package (PoP) becomes increasingly popular.

FIGS. 1A-1K are cross-sectional views of a method for fabricating a substrate used in PoP according to the prior art.

As shown in FIG. 1A, a substrate 10 having a first surface 10a and a second surface 10b opposing the first surface 10a is provided. A plurality of first electrical connecting pads 11a and a first circuit 12a are disposed on the first surface 10a of the substrate 10. A plurality of second electrical connecting pads and a second circuit 12a are formed on the second surface 10a of the substrate 10. The substrate 10 has a plurality of conductive vias 101 penetrating the first surface 10a and the second surface 10b and electrically connecting the first circuits 12a with the second circuits 12b.

As shown in FIG. 1B, a first conductive layer 13a is formed on the first surface 10a, the first circuit 12a and the first electrical connecting pad 11a by a sputtering method, and a second connecting conductive layer 13b is formed on the second surface 10b, the second circuits 12b and the second electrical connecting pads 11b. In an embodiment, the first conductive layer 13a and the second conductive layer 13b are formed by copper.

As shown in FIG. 1C, a first resist layer 14a is formed on the first conductive layer 13a, and a second resist layer 14b with a plurality second resist vias 140b is formed. The second resist openings 140 correspond in position with the second electrical connecting pads 11b.

As shown in FIG. 1D, a surface treatment layer 15 is formed on the second conductive layer 13b in each of the second resist openings 140b, and the first resist layer 14a and the second resist layer 14b are removed.

As shown in FIG. 1E, a portion of the first conductive layer 13a and a portion of the second conductive layer 13b that are not covered by the surface treatment layer 15 are removed by etching.

As shown in FIG. 1F, a first insulative protection layer 16a having a plurality of first insulative protection layer openings 160a is formed on the first surface 10a, the first circuits 12a, and the first electrical connecting pads 11a. Each of the first insulative protection layer openings 160a is exposed from a corresponding one of the first electrical connecting pads 11a. A second insulative protection layer 16b having a plurality of first insulative protection layer openings 160a is formed on the first surface 10a, the first circuits 12a, and the first electrical connecting pads 11a. The second insulative protection layer openings 160a are exposed from the surface treatment layer 15.

As shown in FIG. 1G a third resist layer 17a having third resist layer openings 170a is formed on the first insulative protection layer 16a. The third resist openings 170a are exposed from the first insulative protection via 160a. A fourth resist layer 17b is formed on the second insulative protection layer 16b and the surface treatment layer 15, and each of the third resist opening 170a is width than a corresponding one of the first insulative protection openings 160a to allow proper positioning to take place.

As shown in FIG. 1H, a third conductive layer 18 is formed on the third resist layer 17a, the first insulative protection layer 16a and the first electrical connecting pad 11a by chemical plating on the exposed surface thereof.

As shown in FIG. 1I, a metal layer 19 is formed on the third conductive layer 18 through electroplating. In an embodiment, the metal layer 19 is made of copper.

As shown in FIG. 1J, a portion of the metal layer 19 and a portion of the third conductive layer 18 are ground and removed, so as to define the metal pillar 10′ that is electrically connected with the first electrical connecting pad 11a within the third resist opening 170.

As shown in FIG. 1K, the third resist layer 17a and the fourth resist layer 17b are removed. The metal pillar 19′ has a neck part that narrower at the position of the first insulative protection via 160a.

However, in the method of fabricating the conventional substrate, after electroplating to form the metal layer, in order to obtain the metal pillars with the same height, grinding is used to remove part of the metal layer and a second resist layer 14b with a plurality second resist layer openings 140b is formed. This grinding process may easily cause raw edges on the metal pillar, leading to short circuit of between the fine pitched metal pillars, resulting in yield reduction. Moreover, if etching is used to substitute grinding method to remove part of the metal layer, the inability to control the depth of etching may also lead to unequal heights of the metal pillars; moreover the neck part of the metal pillar may become a weak point in torque.

Accordingly, there is an urgent need to solve the foregoing problems encountered in the prior art.

### SUMMARY OF THE INVENTION

In view of the foregoing problems, the present invention provides a method of fabricating a package substrate, comprising: providing a substrate having a first surface, a second surface opposing the first surface, and a plurality of first electrical connecting pads disposed on the first surface; mounting a metal board on the first electrical connecting pads; and patterning the metal board to define a plurality of metal pillars corresponding to the first electrical connecting pads.

In an embodiment, patterning the metal board comprises: forming a patterned resist layer on the metal board; removing a portion of the metal board that is not covered by the patterned resist layer; and removing the patterned resist layer.

In an embodiment, when a patterned resist layer is formed on the metal board, a third resist layer is formed on the second surface, and is removed when the patterned resist layer is removed. The metal board is removed by etching, and the metal layer is made of copper.

In an embodiment, a plurality of second electrical connecting pads are formed on the second surface, a surface treatment layer is formed on each of the second electrical connecting pads, and the surface treatment layer is made of nickel/gold.

In an embodiment, the surface treatment layer is formed before the metal board is mounted on the first electrical connecting pads by: forming a first conductive layer on the first surface and the first electrical connecting pads, and forming a second conductive layer on the second surface and the second electrical connecting pads; forming a first resist layer on the first conductive layer, and forming a second resist layer having a plurality of resist layer openings on the second conductive layer, each of the resist layer opening corresponding to each of the second electrical connecting pads; forming a surface treatment layer on the second conductive layer of the resist layer opening; removing the first resist layer and the second resist layer; and removing a portion of the first conductive layer and a portion of the second conductive layer that are not covered by the surface treatment layer.

In an embodiment, the first conductive layer and the second conductive layer are formed by sputtering, and the first conductive layer and the second conductive layer are removed by etching. After the metal pillars are formed, an insulative protection layer having a plurality of insulative protection layer openings are formed on the second surface.

In an embodiment, a first circuit and a second circuit are formed on the first surface and the second surface of the substrate body, respectively. The substrate body further comprises a plurality of conductive vias penetrating the first surface and the second surface, and electrically connecting the first circuit with the second circuit. The metal board is mounted on the first electrical connecting pads by soldering or ultrasonic welding methods.

A package substrate provided by the present invention comprises: a substrate body having a first surface, a second surface opposing the first surface, and a plurality of first electrical connecting pads disposed on the first surface; and a plurality of metal pillars disposed on the first electrical connecting pads, wherein each of the metal pillars is wider than a corresponding one of the first electrical connecting pads.

In an embodiment, the metal pillar is made of copper. In an embodiment, the package substrate further comprises a plurality of second electrical connecting pads disposed on the second surface, and a surface treatment layer formed on each of the second electrical connecting pads.

In an embodiment, the surface treatment layer is made of nickel/gold, and an insulative protection layer having a plurality of insulative protection layer openings is formed on the second surface.

In an embodiment, the first circuit and the second circuit are formed on the first surface and the second surface of the substrate body, respectively. The substrate body further comprises a plurality of conductive vias penetrating the first surface and the second surface and electrically connecting the first circuit with the second circuit.

In summary, the present invention involves mounting a metal board to the first electrical connecting pads, and the metal board is patterned to form a plurality of metal pillars. Thus, without the need of grinding, the problem of short circuit resulted from raw edges due to grinding of the metal pillars can be effectively solved by the present invention.

### BRIEF DESCRIPTION OF DRAWINGS

The present invention can be more fully understood by reading the following detailed description of the preferred embodiments, with reference made to the accompanying drawings, wherein:

FIGS. 1A-1K are cross-sectional views illustrating a method of fabricating a conventional package on package (PoP); and

FIGS. 2A-2I are cross-sectional views illustrating a method of fabricating a package substrate according to the present invention, wherein FIG. 2H′ is another embodiment of FIG. 2H.

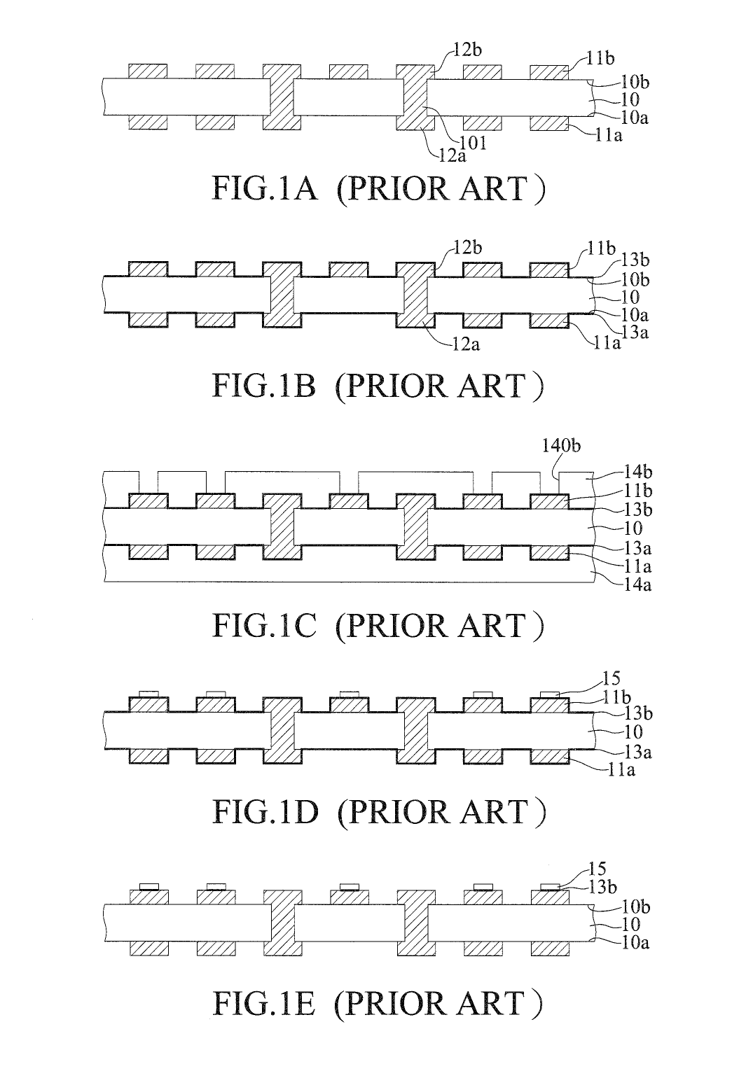

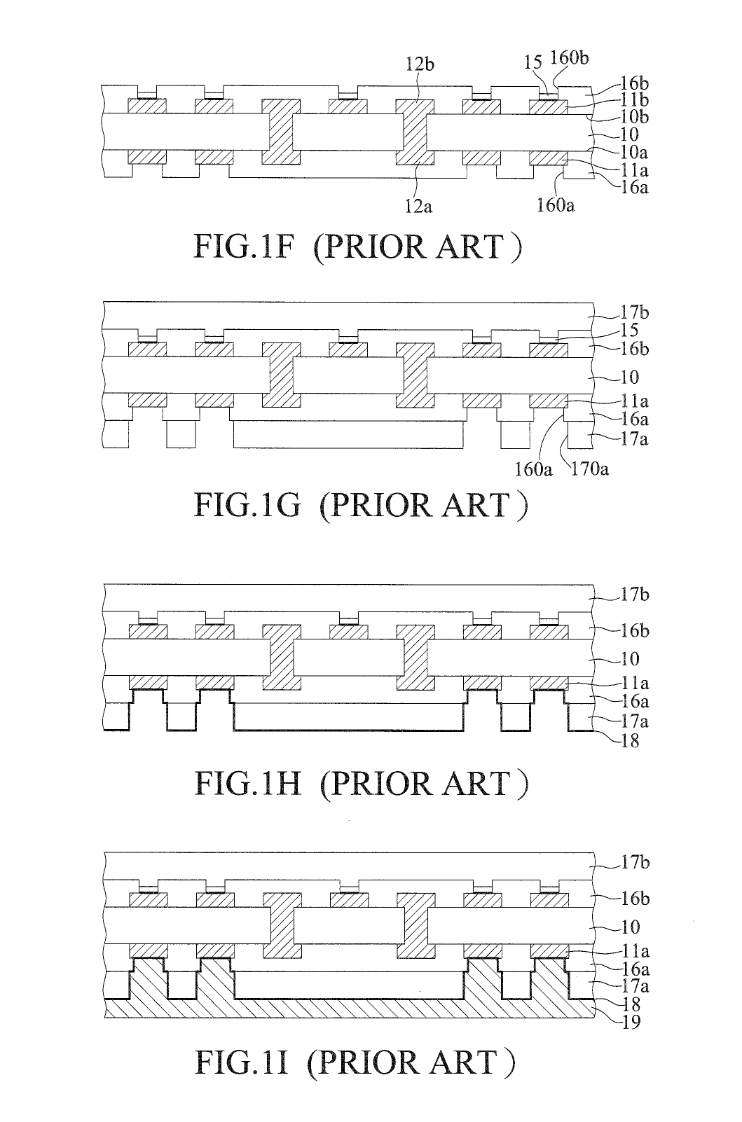

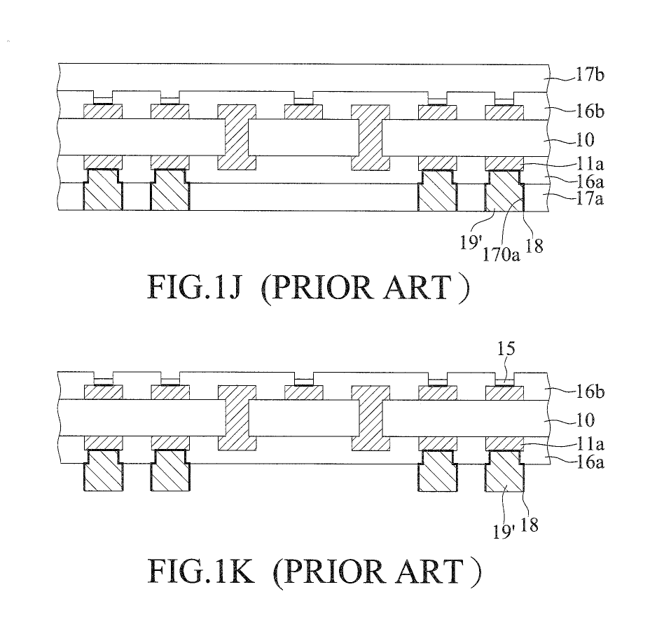

### DETAILED DESCRIPTION OF PREFERRED EMBODIMENTS

The present invention is described in the following with specific embodiments, so that one skilled in the pertinent art can easily understand other advantages and effects of the present invention from the disclosure of the present invention.

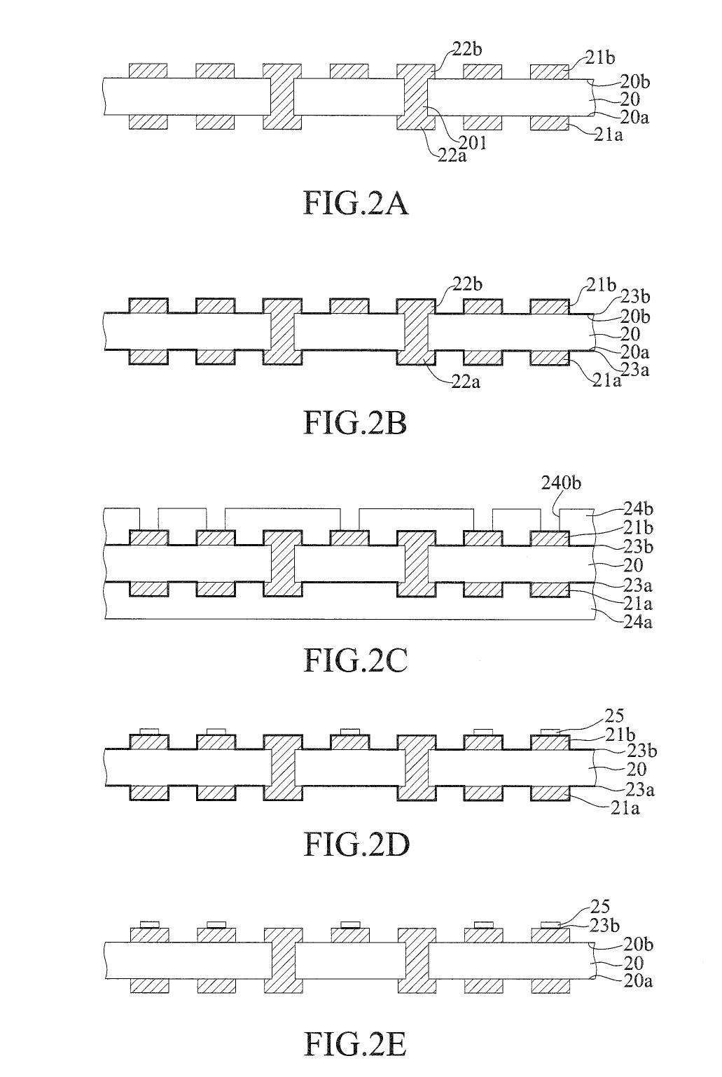

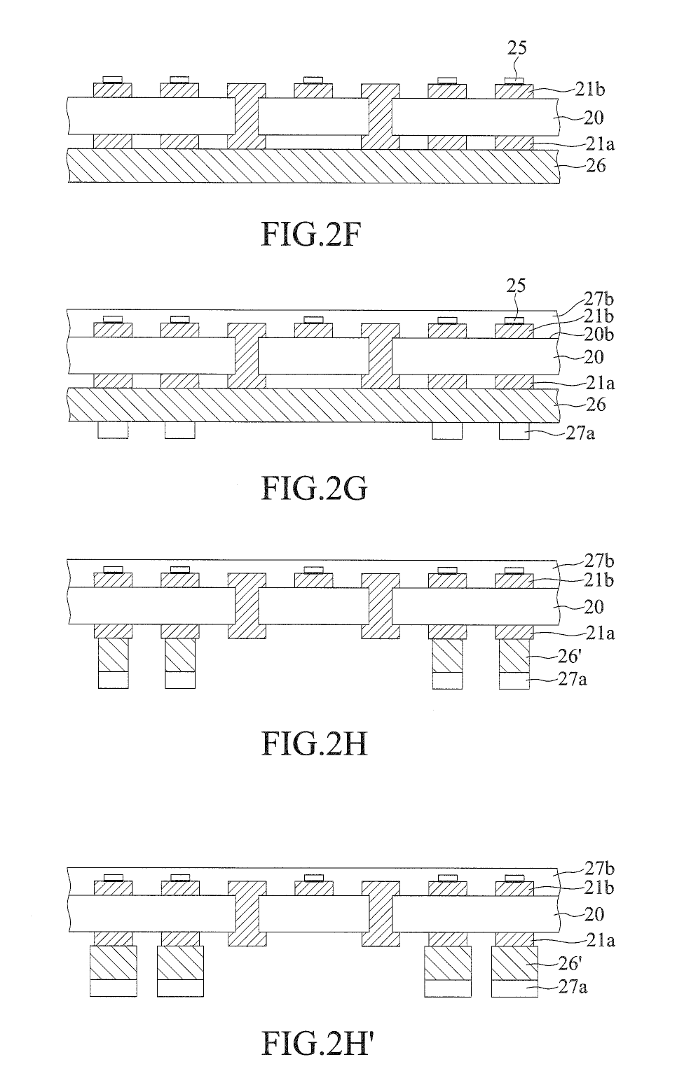

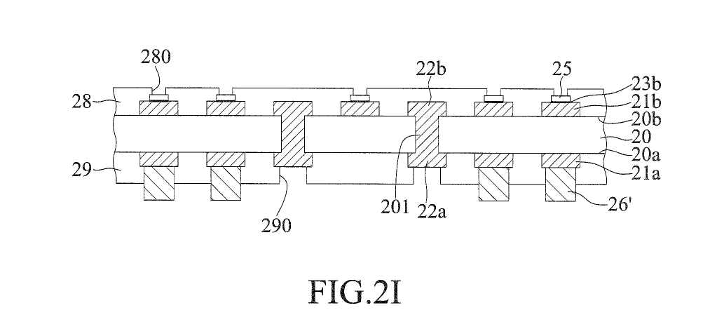

FIGS. 2A-2I are cross-sectional views illustrating a method of fabricating a package substrate according to the present invention.

As shown in FIG. 2a, a substrate body 20 is provided that has a first surface 20a, a plurality of first electrical connecting pads 21a disposed on the first surface 20a, a first circuit 22a formed on the first surface 20a, a second surface 20b opposing the first surface 20a, a plurality of second electrical connecting pads 21b disposed on the second surface 20b, and a second circuits 22b formed on the second surface 20b. The substrate body 20 has a plurality of conductive vias 201 penetrating the first surface 20a and the second surface 20b and electrically connecting the first circuit 22a with the second circuit 22b.

As shown in FIG. 2B, a first conductive layer 23a is formed on the first surface 20a, the first circuits 22a, and the first electrical connecting pads 21a through sputtering, and a second conductive layer 23b is formed on the second surface 20b, the second circuits 22b, and the second electrical connecting pads 21b through sputtering. In an embodiment, the first conductive layer 23a and the second conductive layer 23b are made of copper.

As shown in FIG. 2C, a first resist layer 24a is formed on the first conductive layer 23a, and a second resist layer 24b having a plurality of second resist layer openings 240b is formed on the second conductive layer 23b. The second resist openings 240b correspond in position to the second electrical connecting pads 21b.

As shown in FIG. 2D, a surface treatment layer 25 is formed on the second conductive layer 23b in each of the second resist layer openings 240b, and the first resist layer 24a and the second resist layer 24b are removed.

As shown in FIG. 2E, a portion of the first conductive layer 23a and a portion of the second conductive layer 23b that are not covered by the surface treatment layer 25 are removed by etching.

As shown in FIG. 2F, a metal board 26 is mounted on the electrical connecting pad 21a through soldering or ultrasonic welding.

As shown in FIG. 20, a patterned resist layer 27a is formed on the metal board 26 at the position corresponding to the first electrical connecting pads 21a, and a third resist layer 27b is formed on the second surface 20b, the second electrical connecting pads 21b and the surface treatment layer 25.

As shown in FIG. 2H, a portion of the metal board 26 that is not covered by the patterned resist layer 27a and the defined metal pillars 26′ corresponding to the first electrical connecting pads 21a are removed. Each of the metal pillars 26′ is wider than a corresponding one of the electrical connecting pads 21a, as shown in FIG. 2H′, so as to increase the overall torque strength.

As shown in FIG. 2I, the patterned resist layer 27a is removed, an insulative protection layer 28 having a plurality of insulative protection layer openings 280 is formed on the second surface 20b, the insulative protection layer openings 290 are exposed from the metal pillar 26′ and a portion of the first circuits 22a.

In comparison with the conventional technology, a metal board is mounted on the first electrical connecting pads, and is patterned to define a plurality of metal pillars. As a result, without the need of grinding, the problem of short circuit resulted from raw edges due to grinding of the metal pillars can be effectively solved by the present invention. In addition, as the top surface of the metal pillar is covered by the resist layer, during the pattering process of the metal board, the drawback of unequal heights of the metal pillars can be obviated.

The present invention has been described using exemplary preferred embodiments. However, it is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A method of fabricating a package substrate, comprising:
providing a substrate having a first surface, a second surface opposing the first surface, and a plurality of first electrical connecting pads disposed on the first surface;
mounting a metal board on the first electrical connecting pads; and
patterning the metal board to define a plurality of metal pillars corresponding to the first electrical connecting pads.

2. The method of claim 1, wherein patterning the metal board comprises:
forming a patterned resist layer on the metal board;
removing a portion of the metal board that is not covered by the patterned resist layer; and
removing the patterned resist layer.

3. The method of claim 2, wherein forming the patterned resist layer comprises forming a third resist layer on the second surface, and removing the third resist with the removal of the patterned resist layer.

4. The method of claim 2, wherein the portion of the metal board is removed by etching.

5. The method of claim 1, wherein the metal board is made of copper.

6. The method of claim 1, further comprising disposing a plurality of second electrical connecting pads on the second surface, and forming a surface treatment layer on each of the second electrical connecting pads.

7. The method of claim 6, wherein the surface treatment layer is made of nickel/gold.

8. The method of claim 6, wherein the surface treatment layer is formed before the metal board is mounted on the first electrical connecting pads by:
forming a first conductive layer on the first surface and the first electrical connecting pads, and forming a second conductive layer on the second surface and the second electrical connecting pads;
forming a first resist layer on the first conductive layer, and forming on the second conductive layer a second resist layer that has a plurality of resist layer openings, each of which corresponds to each of the second electrical connecting pads;
forming a surface treatment layer on the second conductive layer of the resist layer opening;
removing the first resist layer and the second resist layer; and
removing a portion of the first conductive layer and a portion of the second conductive layer that are not covered by the surface treatment layer.

9. The method of claim 8, wherein the first conductive layer and the second conductive layer are formed by sputtering.

10. The method of claim 8, wherein the first conductive layer and the second conductive are removed by etching.

11. The method of claim 1, further comprising forming an insulative protection layer having a plurality of insulating protection layer openings on the second surface after the metal pillars are defined.

12. The method of claim 1, further comprising forming a first circuit and a second circuit on the first surface and the second surface of the substrate, respectively.

13. The method of claim 12, wherein the substrate comprises a plurality of conductive vias penetrating the first surface and the second surface and electrically connecting the first circuit with the second circuit.

14. The method of claim 1, wherein the metal board is mounted on the first electrical connecting pads by a soldering or ultrasonic welding method.

15. A package substrate, comprising:
a substrate body having a first surface, a second surface opposing the first surface, and a plurality of first electrical connecting pads disposed on the first surface; and
a plurality of metal pillars disposed on the first electrical connecting pads, wherein each of the metal pillars is wider than a corresponding one of the first electrical connecting pads.

16. The package substrate of claim 15, wherein the metal pillar is made of copper.

17. The package substrate of claim 15, further comprising a plurality of second electrical connecting pads disposed on the second surface, and a surface treatment layer formed on the second electrical connecting pads.

18. The package substrate of claim 17, wherein the surface treatment layer is made of nickel/gold.

19. The package substrate of claim 15, further comprising an insulative protection layer formed on the second surface and having a plurality of insulative protection layer openings.

20. The package substrate of claim 15, further comprising a first circuit and a second circuit disposed on the first surface and the second surface of the substrate body, respectively.

21. The package substrate of claim 20, wherein the substrate body further comprises a plurality of conductive vias penetrating the first surface and the second surface and electrically connecting the first circuit and the second circuit.
